(19) United States
(12) Patent Application Publication
(10) Pub. No.: US 2008/0128285 A1
(43) Pub. Date: Jun. 5, 2008

(54) ELECTROCHEMICAL GAS SENSOR CHIP AND METHOD OF MANUFACTURING THE SAME

(75) Inventors: Seung Eon MOON, Daejeon (KR); Eun Kyoung KIM, Daejeon (KR); Hong Yeol LEE, Chungcheongbuk-do (KR); Jong Hyurk PARK, Daegu (KR); Kang Ho PARK, Daejeon (KR); Jong Dae KIM, Daejeon (KR); Seok Hong MIN, Gangwon-Do (KR); Byung Gil JUNG, Gangwon-Do (KR); Seung Chul HA, Gyeonggi-do (KR)

Correspondence Address: RABIN & Berdo, PC, 1101 14TH STREET, NW, SUITE 500, WASHINGTON, DC, 20005, US

(73) Assignees: Electronics and Telecommunications Research Institute, Daejeon (KR); SENKO Co., Ltd., Gangwon-Do (KR)

(21) Appl. No.: 11/944,232

(22) Filed: Nov. 21, 2007

(30) Foreign Application Priority Data
Dec. 4, 2006 (KR) 10-2006-0121377
Jun. 18, 2007 (KR) 10-2007-0059266

(51) Int. Cl. G01N 27/407; C23C 14/24; C23C 14/34

(52) U.S. Cl. 205/80; 204/192.1; 204/412; 204/424

(57) ABSTRACT

An electrochemical gas sensor and a method of manufacturing the same are provided. The electrochemical gas sensor includes: a substrate; an electrode patterned on the substrate; a solid electrolyte layer having proton conductivity formed on the substrate having the patterned electrode; and a hydrophobic microporous membrane formed on the solid electrolyte layer. The gas sensor chip is easily integrated with a driving circuit and uses a solid electrolyte layer, and thus it can be manufactured in a smaller size and in a large area process.

### CROSS-REFERENCE TO RELATED APPLICATION

This application claims priority to and the benefit of Korean Patent Application No. 2006-121377, filed Dec. 4, 2006, and No. 2007-59266, filed Jun. 18, 2007, the disclosure of which is incorporated herein by reference in its entirety.

### BACKGROUND

1. Field of the Invention

The present invention relates to an electrochemical gas sensor chip and a method of manufacturing the same, and more particularly, to an electrochemical gas sensor chip using a solid electrolyte, and a method of manufacturing the same.

This work was supported by the IT R&D program of Ministry of Information and Communication/Institute for Information Technology Advancement [2006-S-006-01, Components/Module technology for Ubiquitous Terminals.]

2. Discussion of Related Art

Gas sensors have been applied to various applications such as the automobile industry, the environmental industry, the food and beverage industry, the robotics industry, etc., and related technology thereto has been studied.

Although a semiconductor gas sensor using a conductivity change in an oxide semiconductor by contact between an oxidative gas and a reductive gas is commercially produced, the sensor still faces technical limitations for use in portable devices when a heater consumes a large amount of power, which raises operation temperature of the oxide semiconductor to sense a gas.

Also, an optical gas sensor determining the kind of gas by a change in an ultraviolet (UV) spectrum passing through sensing gas is commercially produced, but it is still not suitable for use in portable devices because a UV source or detector is difficult to downsize, power consumption is high, and the sensor is also difficult to downsize due to a long optical path needed to increase sensitivity.

Another type of gas sensor is an electrochemical gas sensor 10, which is currently commercialized and is illustrated in FIG. 1. In the gas sensor 10, each toxic gas diffused through a gas inlet is introduced through a porous membrane 11, and then generates proton ions and electrons by one of the reactions of Formulas 1 to 4 in a catalytic electrode material of a working electrode 12 formed in the porous membrane.

Ozone (O₃) gas sensor

Working electrode: O₃+2e⁻+2H⁺→O₂+H₂O

Counter electrode: 2H₂O→O₂+4H⁺+4e⁻ [Formula 1]

Carbon monoxide (CO) gas sensor

Working electrode: CO+H₂O→CO₂+2H⁺+2e⁻

Counter electrode: 2H⁺+2e⁻+½O₂→H₂O [Formula 2]

Nitrogen dioxide (NO₂) gas sensor

Working electrode: NO₂+2H⁺+2e⁻→NO+H₂O

Counter electrode: H₂O→2H⁺+2e⁻+½O₂ [Formula 3]

Sulfur dioxide (SO₂) gas sensor

Working electrode: SO₂+H₂O→SO₄²⁻+4H⁺+2e⁻

Counter electrode: 2H⁺+2e⁻+½O₂→H₂O [Formula 4]

The generated electrons moving to the counter electrode via a current collector react with the generated proton ions moving to the counter electrode via an electrolyte so as to form water according to the above-described formula, and thus generate current. Here, the current is directly proportional to the concentration of gas existing outside, and thus the gas concentration is determined by sensing the current. The porous membrane under the inlet allows gas to flow into the sensor from outside and not to flow the electrolyte out, and determines an amount of the gas coming from outside. The porous membrane is used as a substrate for forming a working electrode using a noble metal electrode material having excellent catalytic activity. A separator is disposed under the working electrode, which is sufficiently soaked in the electrolyte, and allows current to be flowed only by a counter electrode or reference electrode, which is disposed under the working electrode, and ions.

The underlying counter electrode allows the proton ion formed in the working electrode and then moved through the electrolyte to be reacted with the electron moved from the working electrode to the counter electrode through an external circuit, and the reference electrode allows the working electrode to maintain a constant potential. The electrolyte filled in the sensor includes an acidic/basic solution having excellent ionic conductivity in a liquid state.

For selective sensing characteristics by gases, it is necessary to discriminate the kind of the electrodes and the electrolytes and to change the voltage applied between the reference electrode and the working electrode.

Compared with a semiconductor or optical sensor, the conventional electrochemical gas sensor is difficult to equip in a portable device, such as a mobile phone, due to the sensor's size and stability and because it is operated in room temperature. Furthermore, although the conventional electrochemical gas sensor does not need a light source, and thus consumes less power than a semiconductor or optical sensor, it contains a liquid electrolyte, and thus is large and unstable due to its acidity.

For this reason, many trials using a solid electrolyte instead of a liquid electrolyte have been conducted.

A structure in which a working electrode is formed at one side, a counter electrode and a reference electrode are at the other side, and a polymer layer having excellent proton conductivity is used as an electrolyte is disclosed in U.S. Pat. No. 4,718,991 by Yamazoe et al. Although this structure has electrodes at both sides of the polymer layer having excellent proton conductivity, so it may be made somewhat smaller, it may not be made into a chip to be integrated with a driving circuit.

The electrochemical gas sensor may be normally operated when data about its own properties, such as reaction characteristics with respect to gases (for example, how much gas is output at a certain concentration (ppm)) and sensor characteristics with respect to environmental changes such as external temperature and humidity, has to be included in a microprocessor connected to drive the sensor. Thus, in practice every electrochemical gas sensor has a microprocessor to be normally operated by inputting characteristics of the sensor. However, the current gas sensor may not be integrated on one board together with other elements, which are necessary to be driven, so a sensor chip has to be developed to solve this problem.

A structure having hydrophobic membranes on top and bottom of the structure described above, through which gas or moisture can pass but ions cannot pass, is disclosed in U.S. Pat. No. 6,896,781 by Shen et al. However, in an electrochemical gas sensor having this structure, proton conductivity of an electrolyte may be changed according to a concentration of surrounding moisture, so an actual concentration of sensed gas may be erroneously sensed.

Accordingly, the present inventors have studied and finally completed a chip-type electrochemical gas sensor which is manufactured on a substrate by a semiconductor process, and can be formed in a micromini-sized structure and in a large area process when using a hydrophobic microporous membrane.

### SUMMARY OF THE INVENTION

The present invention is directed to an electrochemical gas sensor chip which can be formed in a micromini-sized structure and in a large area process.

The present invention is also directed to a method of manufacturing an electrochemical gas sensor chip which can be formed in a micromini-sized structure and in a large area process.

One aspect of the present invention provides an electrochemical gas sensor chip, including: a substrate; an electrode patterned on the substrate; a solid electrolyte layer having proton conductivity formed on the substrate having the patterned electrode; and a hydrophobic microporous membrane formed on the solid electrolyte layer.

Another aspect of the present invention provides a method of manufacturing an electrochemical gas sensor chip, including the steps of: preparing a substrate; patterning an electrode on the substrate; forming a solid electrolyte layer having proton conductivity on the substrate having the patterned electrode; and forming a hydrophobic microporous membrane on the solid electrolyte layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a conventional electrochemical gas sensor using a liquid electrolyte;

FIG. 2 is a plan view of an electrochemical gas sensor chip using a solid electrolyte according to an exemplary embodiment of the present invention;

FIG. 3 is a cross-sectional view of the electrochemical gas sensor chip using a solid electrolyte according to the exemplary embodiment of the present invention; and

FIG. 4 is a cross-sectional view of an electrochemical gas sensor chip using a solid electrolyte according to another exemplary embodiment of the present invention.

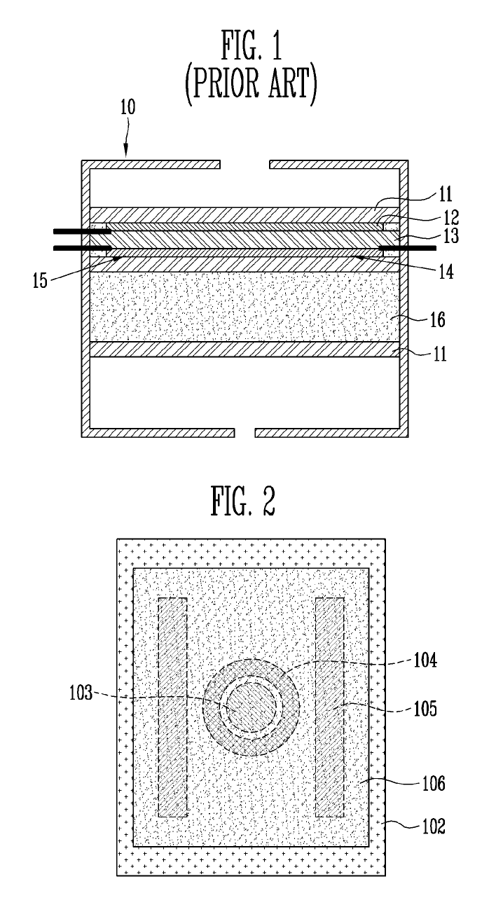

### DETAILED DESCRIPTION

Hereinafter, the present invention will be described in detail with reference to drawings illustrating exemplary embodiments of the present invention.

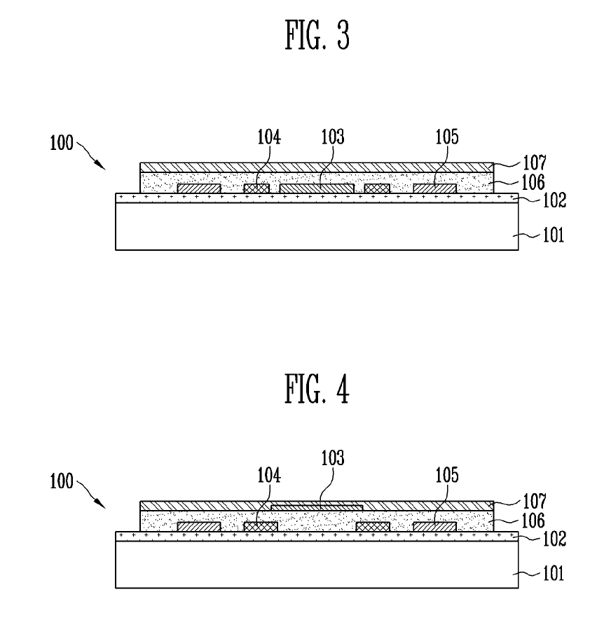

FIGS. 2 and 3 are a plan view and a cross-sectional view of an electrochemical gas sensor chip using a solid electrolyte according to an exemplary embodiment of the present invention, respectively, and FIG. 4 is a cross-sectional view of an electrochemical gas sensor chip using a solid electrolyte according to another exemplary embodiment of the present invention.

Referring to FIGS. 2 and 3, an electrochemical gas sensor chip 100 according to an exemplary embodiment of the present invention includes a substrate 101, an insulating layer 102 formed thereon, a working electrode 103 patterned on the insulating layer 102, a counter electrode 104 and a reference electrode 105, a solid electrolyte layer 106 formed on the patterned electrode, and a hydrophobic microporous membrane 107.

The substrate 101, as a base on which an electrochemical gas sensor is formed, allows the gas sensor chip to be integrated with a driving circuit. The substrate 101 may be formed of one selected from materials such as silicon, polycarbonate, quartz, GaAs, InP and glass, and preferably silicon. A thickness of the substrate may be determined by the size and thickness of the electrochemical gas sensor, preferably, in a range of 0.3 to 1 mm.

While the electrode may be formed directly on the substrate 101, it is preferably formed to buffer a gap between the substrate 101 and the electrode after forming the insulating layer 102. The insulating layer 102 may be a silicon oxide layer. The insulating layer 102 may be formed by annealing. The thickness of the insulating layer 102 may be determined by those skilled in the art in consideration of the thicknesses of the substrate and the electrode, which may be in a range of several tens to thousands of nanometers.

The working electrode 103, the counter electrode 104 and the reference electrode 105 are patterned to be formed on the same surface of the insulating layer 102, or the substrate 101 when the insulating layer 102 is not formed thereon.

The electrodes may be formed of a noble metal material having excellent catalytic activity, and preferably Ag, Au, Pt, Rd, Ir, Ru, Pd or conductive oxide, and more preferably Pt. The working electrode 103, the counter electrode 104 and the reference electrode 105 may be formed of the same material or different materials.

The electrodes may be formed by a dry method used in the general semiconductor process, i.e., sputtering or vacuum deposition, or a chemical vapor deposition method.

Also, the electrodes 103, 104 and 105 formed of the same material may be formed by a single process using a mask or lift-off method or an etching method, which is used in a general semiconductor process, and the electrodes 103, 104 and 105 formed of different materials may be formed by a multiple process using a mask or lift-off method or an etching method.

The examples of the patterned working electrode 103, counter electrode 104 and reference electrode 105 on the insulating layer 102 are illustrated in FIG. 2. The working electrode 103 is formed in a circular shape in the middle of the insulating layer 102, the counter electrode 104 is formed in a circular shape around the working electrode 103, and the reference electrode 105 is formed in a bar shape at both sides thereof.

The counter electrode 104 and the reference electrode 105 may be connected to be in electrical contact with each other.

The working electrode 103, the counter electrode 104 and the reference electrode 105 may be formed to the same thickness, which may be in a range of several tens to thousands of nanometers.

The solid electrolyte layer 106 may be formed on the patterned electrode by a wet etching process such as spin coating or screen printing, using digested polymer having excellent proton conductivity. The polymer having excellent proton conductivity may be one generally used in this field, and preferably a 5 to 20 wt % solution of Nafion®, commercially available from Dupont.

The thickness of the solid electrolyte layer 106 may be determined by the size of the sensor, and the thicknesses of the substrate and the electrode, which may be in a range of several tens to thousands of micrometers.

Meanwhile, after forming the solid electrolyte layer 106 having excellent proton conductivity, a chemical treatment process may be performed to maximize the proton conductivity. For example, the Nafion® layer is treated in a boiling 1 to 5 M sulfur solution for 1 to 4 hours.

The hydrophobic microporous membrane 107 may be formed on the solid electrolyte layer 106 to minimize an effect on the membrane by environmental changes such as changes in external temperature and humidity.

The hydrophobic microporous membrane 107 may have micropores through which sensing gas can pass but ions or moisture cannot pass, and particularly may be formed of polytetrafluoroethylene (PTFE), silica gel, etc.

Referring to FIG. 4, the electrochemical gas sensor chip 100 according to another embodiment of the present invention includes a substrate 101, an insulating layer 102 formed on the substrate 101, a counter electrode 104 and a reference electrode 105 which are formed on the insulating layer 102, a solid electrolyte layer 106 formed on the electrodes, a working electrode 103 formed on the solid electrolyte layer 106, and a hydrophobic microporous membrane 107.

The description of the substrate 101, the insulating layer 102, the working electrode 103, the counter electrode 104, the reference electrode 105, the solid electrolyte layer 106 and the hydrophobic microporous membrane 107, which constitute the gas sensor chip illustrated in FIG. 4, is the same as that of the elements of the chip 100 illustrated in FIGS. 2 and 3.

However, the chip 100 illustrated in FIG. 4 has the counter electrode 104 and the reference electrode 105, which are formed on the same surface of the insulating layer 102 or the substrate 101 when the insulating layer is not formed, and the working electrode 103 which is formed on the solid electrolyte layer 106.

The electrochemical gas sensor chip may select sensing gas depending on a voltage applied between the counter electrode and the reference electrode, and the kind of the electrode.

An electrochemical gas sensor chip and a method of manufacturing the same according to the present invention have the following advantages.

First, the gas sensor according to the present invention has a chip structure and thus can be easily integrated with a driving circuit.

Second, the gas sensor according to the present invention can be mass-produced by a semiconductor process to be implemented on a substrate.

Third, the gas sensor according to the present invention uses a hydrophobic microporous membrane on a solid electrolyte layer, thereby preventing evaporation of water molecules from the solid electrolyte layer, and thus can be used for quite a long time without maintaining constant humidity using a separate water reservoir.

Fourth, the gas sensor according to the present invention can be downsized because it does not use a liquid material such as a liquid electrolyte, and thus may be equipped in a portable terminal such as a mobile phone.

Fifth, the gas sensor according to the present invention can be integrated with a driving circuit for the sensor by a semiconductor process (a sensor chip having a driving circuit therein can be developed).

While the invention has been shown and described with reference to certain exemplary embodiments thereof, it will be understood by those skilled in the art that various changes in form and details may be made therein without departing from the spirit and scope of the invention as defined by the appended claims.

1. An electrochemical gas sensor chip, comprising:
a substrate;
an electrode patterned on the substrate;
a solid electrolyte layer having proton conductivity formed on the substrate having the patterned electrode; and
a hydrophobic microporous membrane formed on the solid electrolyte layer.

2. The electrochemical gas sensor chip according to claim 1, wherein the substrate is formed of one selected from the group consisting of silicon, polycarbonate, quartz, GaAs, InP and glass.

3. The electrochemical gas sensor chip according to claim 1, wherein the patterned electrode is configured such that a working electrode, a counter electrode and a reference electrode are formed on the same surface of the substrate.

4. The electrochemical gas sensor chip according to claim 1, wherein the patterned electrode is configured such that a counter electrode and a reference electrode are formed on the same surface of the substrate, and a working electrode is formed on the solid electrolyte layer.

5. The electrochemical gas sensor chip according to claim 4, wherein the reference electrode is connected with the counter electrode.

6. The electrochemical gas sensor chip according to claim 3, wherein the reference electrode is connected with the counter electrode.

7. The electrochemical gas sensor chip according to claim 1, wherein the electrode is formed of one selected from the group consisting of silver, gold, platinum, rhodium, iridium, ruthenium, palladium and conductive oxide.

8. The electrochemical gas sensor chip according to claim 1, wherein the solid electrolyte layer having proton conductivity is a Nafion® layer.

9. The electrochemical gas sensor chip according to claim 1, wherein the hydrophobic microporous membrane has micropores through which gas passes but ions or moisture cannot pass.

10. A method of manufacturing an electrochemical gas sensor chip, comprising the steps of:
preparing a substrate;
patterning an electrode on the substrate;
forming a solid electrolyte layer having proton conductivity on the substrate having the patterned electrode; and
forming a hydrophobic microporous membrane on the solid electrolyte layer.

11. The method according to claim 10, wherein the electrode is formed by sputtering, vacuum deposition or chemical vapor deposition.

12. The method according to claim 10, wherein the solid electrolyte layer is formed by a wet process.

13. The method according to claim 10, wherein the patterned electrode is configured such that a working electrode, a counter electrode and a reference electrode are formed on the same surface of the substrate.

14. The method according to claim 10, wherein the patterned electrode is configured such that a counter electrode and a reference electrode are formed on the same surface of the substrate, and a working electrode is formed on the solid electrolyte layer.
